(19) United States
(12) Patent Application Publication
(10) Pub. No.: US 2014/0144501 A1
(43) Pub. Date: May 29, 2014

(54) METHOD OF FABRICATING A TRANSPARENT ELECTRODE AND A DYE-SENSITIZED SOLAR CELL USING THE TRANSPARENT ELECTRODE

(71) Applicant: Electronics and Telecommunications Research Institute, Daejeon (KR)

(72) Inventors: Mi Hee Jung, Daejeon (KR); Moo Jung Chu, Daejeon (KR)

(21) Appl. No.: 13/920,127

(22) Filed: Jun. 18, 2013

(30) Foreign Application Priority Data
Nov. 26, 2012 (KR) 10-2012-0134658

(51) Int. Cl. H01G 9/20; H01L 31/0224

(52) U.S. Cl. CPC H01G 9/204; H01L 31/022483
USPC 136/256; 438/609

(57) ABSTRACT

A method of fabricating a transparent electrode includes preparing conductive nanoparticles, preparing a metal oxide sol, mixing and reacting the conductive nanoparticles with the metal oxide sol to form a metal oxide solution including a metal oxide combined with the conductive nanoparticles, coating the metal oxide solution on a substrate, and performing an annealing process on the coated metal oxide solution.

### CROSS-REFERENCE TO RELATED APPLICATIONS

This U.S. non-provisional patent application claims priority under 35 U.S.C. §119 to Korean Patent Application No. 10-2012-0134658, filed on Nov. 26, 2012, the entirety of which is incorporated by reference herein.

### BACKGROUND

The inventive concept relates to a method of fabricating a transparent electrode and a dye-sensitized solar cell using the transparent electrode and, more particularly, to a method of fabricating a transparent electrode including a metal oxide combined with silicon nanoparticles and a dye-sensitized solar cell using the transparent electrode.

Solar cells convert solar energy into electrical energy. The solar cells may include a compound solar cell using a compound semiconductor, a dye-sensitized solar cell including dye adsorbed on surfaces of nano crystal particles, a solar cell using organic molecules, a PN-junction type solar cell, and a photoelectrochemical solar cell. The number of photons reaching a photoelectric conversion layer may be maximized and/or light loss caused by surface reflection may be minimized for increasing efficiency of the solar cells. An anti-reflection layer may be used for reducing the light loss caused by the surface reflection.

### SUMMARY

Embodiments of the inventive concept may provide a method of fabricating a transparent electrode capable of improving luminance efficiency of a solar cell.

Embodiments of the inventive concept may also provide a dye-sensitized solar cell having improved luminance efficiency.

In one aspect, a method of fabricating a transparent electrode may include: preparing conductive nanoparticles; preparing a metal oxide sol; mixing and reacting the conductive nanoparticles with the metal oxide sol to form a metal oxide solution including a metal oxide combined with the conductive nanoparticles; coating the metal oxide solution on a substrate; and performing an annealing process on the coated metal oxide solution.

In an embodiment, preparing the conductive nanoparticles may include: forming conductive nanoparticles having hydrogen end-groups; and reacting the conductive nanoparticles having the hydrogen end-groups with an organic compound to form the conductive nanoparticles.

In an embodiment, forming the conductive nanoparticles having the hydrogen end-groups may include: preparing a solvent in which a compound including conductive ions dissolves; preparing an organic compound solvent including a reductant; and mixing and reacting the solvent including the conductive ions with the organic compound solvent including the reductant to form the conductive nanoparticles having the hydrogen end-groups.

In an embodiment, the organic compound solvent may include allylamine (C₃H₅NH₂).

In an embodiment, the reductant may include a lithium-aluminum hydride (LiAlH₄) solution.

In an embodiment, the conductive nanoparticles may be silicon particles functionalized with —NH₂.

In an embodiment, preparing the metal oxide sol may include: preparing a metal oxide precursor solution; dissolving the metal oxide precursor solution in an organic solvent mixed with an alcohol-based solution; and reflexing the organic solvent including the metal oxide precursor solution.

In an embodiment, the metal oxide precursor solution may include zinc acetate dehydrate [Zn(CH3COO)2.(2H)2O].

In an embodiment, the organic solvent may include ethanolamine (CHOC₂CH₂NH₂).

In an embodiment, the alcohol-based solution may be a mixed solution of methanol and 2-methoxy ethanol in a ratio of 1:1.

In an embodiment, the conductive nanoparticle may be combined with the metal oxide by —C═N bond

In another aspect, a dye-sensitized solar cell may include: a lower substrate; a lower transparent electrode disposed on the lower substrate; a semiconductor electrode layer disposed on the lower transparent electrode; and an upper electrode disposed on the semiconductor electrode layer. The lower transparent electrode includes a transparent conductive oxide substrate and a metal oxide thin layer coated on the transparent conductive oxide substrate; and the metal oxide thin layer includes a metal oxide combined with conductive particles.

In an embodiment, the lower transparent electrode may have a refractive index higher than a refractive index of the lower substrate.

In an embodiment, the conductive particles may be silicon particles.

In an embodiment, the metal oxide may be zinc oxide (ZnO).

In an embodiment, the conductive particle may have a nanometer size.

### BRIEF DESCRIPTION OF THE DRAWINGS

The inventive concept will become more apparent in view of the attached drawings and accompanying detailed description.

FIG. 1 is a flowchart illustrating a method of fabricating a transparent electrode according to exemplary embodiments of the inventive concept;

FIGS. 2A and 2B are cross-sectional views illustrating silicon particles according to exemplary embodiments of the inventive concept;

FIG. 3 is a chemical formula illustrating a chemical combination of a zinc oxide precursor and a silicon particle according to exemplary embodiments of the inventive concept;

FIG. 4 is a cross-sectional view illustrating a solar cell including a transparent electrode according to exemplary embodiments of the inventive concept;

FIG. 5 is a graph illustrating a transmittance of a transparent electrode according to exemplary embodiments of the inventive concept;

FIG. 6 is a graph illustrating a transmittance of a zinc oxide thin layer including a silicon particle according to exemplary embodiments of the inventive concept; and

FIG. 7 is a graph illustrating a voltage-current characteristic of a solar cell including a transparent electrode according to exemplary embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

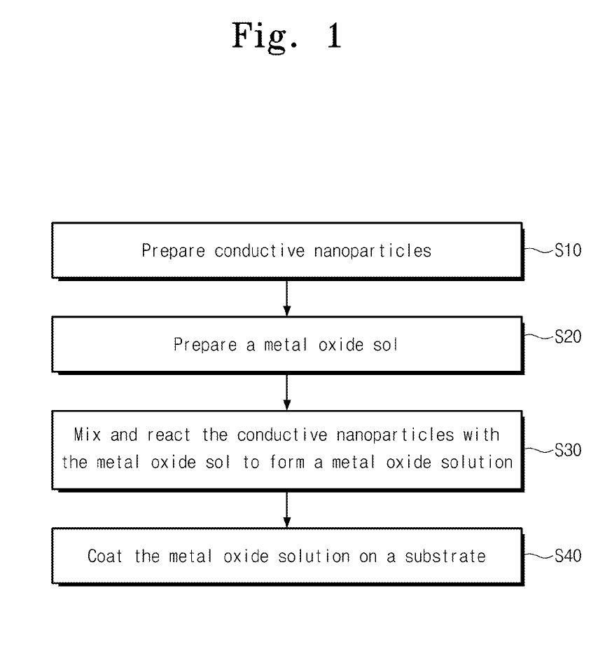

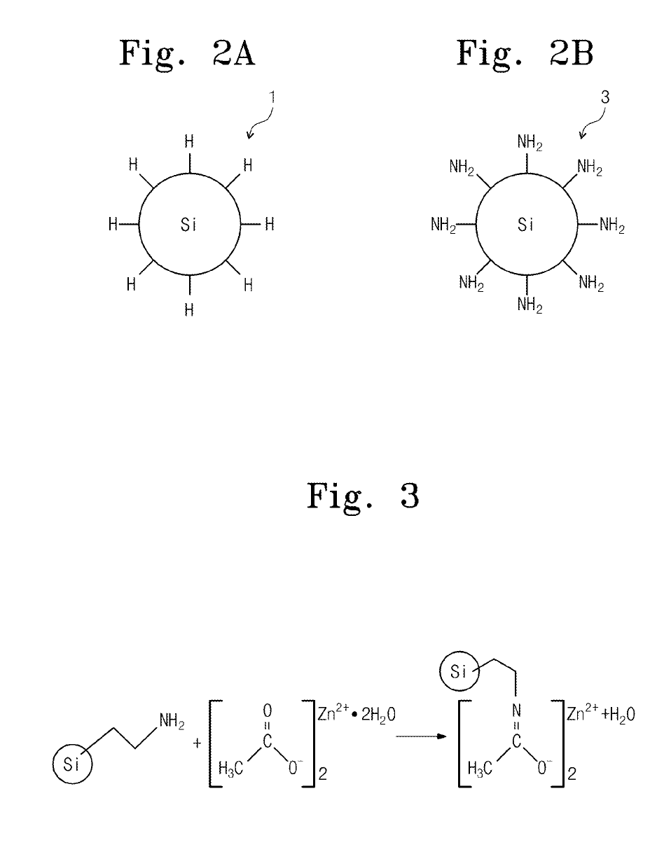

FIG. 1 is a flowchart illustrating a method of fabricating a transparent electrode according to exemplary embodiments of the inventive concept. FIGS. 2A and 2B are cross-sectional views illustrating silicon particles according to exemplary embodiments of the inventive concept. FIG. 3 is a chemical formula illustrating a chemical combination of a zinc oxide precursor and a silicon particle according to exemplary embodiments of the inventive concept.

Referring to FIGS. 1, 2A, 2B, and 3, conductive nanoparticles are prepared (S10).

A compound including conductive ions may be added into a solvent in which a phase transfer catalyst dissolves. The phase transfer catalyst may be tetraoctylammonium bromide (TOAB). The solvent may be anhydrous toluene. The compound including the conductive ions may be silicon tetrachloride (SiCl₄). A reductant may be slowly added into an organic compound solvent. The organic compound solvent may be tetrahydrofuran (TFT). The reductant may be lithium-aluminum hydride (LiAlH₄). The solvent including the conductive ions is mixed with the organic compound solvent including the reductant. The conductive ions may be combined with the reductant to form conductive nanoparticles having hydrogen end-groups. After the conductive nanoparticles having the hydrogen end-groups are formed, methanol may be added for suppressing the combination of the reductant.

An organic compound and a catalytic agent may be added into the solvent including the conductive nanoparticles having the hydrogen end-groups. The organic compound may be allylamine, and the catalytic agent may be chloroplatinic acid (H₂PtCl₆) dissolving in isopropanol. The conductive nanoparticles having the hydrogen end-groups may be chemically combined with the organic compound to form conductive nanoparticles functionalized with —NH₂. The conductive nanoparticles functionalized with —NH₂ may have hydrophilic property.

After the conductive nanoparticles functionalized with —NH₂ are formed, the solvent (e.g., anhydrous toluene) may evaporate and then be removed. The phase transfer catalyst may be removed using a membrane filter. In more detail, the conductive nanoparticles from which the anhydrous toluene are removed may dissolve in water and then the water may be filtered by the membrane filter to separate the tetraoctylammonium bromide (TOAB) not dissolving in the water from the conductive nanoparticles. Finally, the water may be evaporated to obtain pure conductive nanoparticles.

Sizes of the conductive nanoparticles may be within a range of several nm to several tens nm. The conductive nanoparticles may be doped with N-type or P-type dopants.

A metal oxide sol is prepared (S20).

In more detail, a metal oxide precursor solution may be prepared. The metal oxide precursor solution may dissolve in an organic solvent mixed with an alcohol-based solution. For example, the metal oxide precursor may be zinc acetate dehydrate [Zn(CH3COO)2.(2H)2O]. The organic solvent may be, for example, ethanolamine (CHOC₂CH₂NH₂). The alcohol-based solution may be a mixed solution of methanol and 2-methoxy ethanol in a ratio of 1:1. The metal oxide precursor solution and the organic solvent may react with each other in a reflux reaction manner, thereby forming the metal oxide sol.

The conductive nanoparticles may be mixed and react with the metal oxide sol to form a metal oxide solution including a metal oxide combined with the conductive nanoparticles (S30).

In more detail, the conductive nanoparticles functionalized with —NH₂ are mixed with the metal oxide sol. The metal oxide sol mixed with the conductive nanoparticles functionalized with —NH₂ may be inserted into a high temperature high pressure reactor to combine ions of the metal oxide with the conductive nanoparticles functionalized with —NH₂.

The metal oxide solution may be coated on a substrate (S40).

In more detail, the metal oxide solution including the metal oxide combined with the conductive nanoparticles functionalized with —NH₂ may be coated on the substrate and then an annealing process may be performed. The annealing process may be performed at a temperature of about 350 degrees Celsius. The annealing process may be performed to form a transparent metal oxide layer on the substrate. The transparent metal oxide layer may have nano-porousness and a high refractive index. The substrate may be a transparent conductive substrate.

Hereinafter, a method of fabricating a transparent electrode and characteristics of the transparent electrode will be described in more detail with reference to an experiment example according to embodiments of the inventive concept.

Fabrication of Transparent Electrode

### EXPERIMENT EXAMPLE

(Preparation of Silicon Particle)

Silicon tetrachloride (SiCl₄) of 1.5 g is added into an anhydrous toluene solvent in which tetraoctylammonium bromide (TOAB; 0.1 mL, 0.0008 mol) dissolves. A lithium-aluminum hydride (LiAlH₄) solution of a 1M concentration is slowly added into tetrahydrofuran (TFT). The anhydrous toluene solvent including the silicon tetrachloride (SiCl₄) and the tetraoctylammonium bromide (TOAB) is mixed with the tetrahydrofuran (TFT) including the lithium-aluminum hydride (LiAlH₄), thereby forming silicon nanoparticles 1 having hydrogen end-groups, as illustrated in FIG. 2A. The lithium-aluminum hydride (LiAlH₄) solution, the tetraoctylammonium bromide (TOAB), and the anhydrous toluene solvent including the silicon tetrachloride (SiCl₄) reacts for 3 hours and then methanol of 20 mL is added into the anhydrous toluene solvent.

Allylamine (C₃H₅NH₂) of 2 mL and chloroplatinic acid (H₂PtCl₆; 0.05M, 0.4 mL) dissolving in isopropanol are added into the anhydrous toluene solvent including the silicon nanoparticles 1 having the hydrogen end-groups. Thus, silicon particles 3 functionalized with —NH₂ are formed in the anhydrous toluene solvent, as illustrated in FIG. 2B.

Thereafter, the anhydrous toluene solvent is evaporated to be removed. Water is added into the solution to dissolve the silicon particles 3 in the water. The water is filtered using a membrane filter of 0.2 μm to remove the tetraoctylammonium bromide (TOAB) and then the water is removed.

(Preparation of Zinc Oxide Sol)

Zinc acetate dehydrate [Zn(CH3COO)2.(2H)2O] having a concentration of 0.15M and ethanolamine (CHOC₂CH₂NH₂) having a concentration of 0.15M are added into a mixed solution of methanol and 2-methoxy ethanol in a ratio of 1:1. The solution is reflexed at a temperature of 60 degrees Celsius for 3 hours.

(Mixture of Silicon Particles and Zinc Oxide Sol)

The silicon particles 3 functionalized with —NH₂ are mixed with the zinc oxide sol, and then the silicon particles 3 functionalized with —NH₂ and the zinc oxide sol react with each other in a high temperature high pressure reactor at a temperature of 60 degrees Celsius for 24 hours. Thus, as illustrated in FIG. 3, the —NH2 group of the functionalized silicon particle 3 is combined with a —C═O group of the zinc oxide ion to form zinc oxide combined with the silicon nanoparticle 3 through a —C═O group.

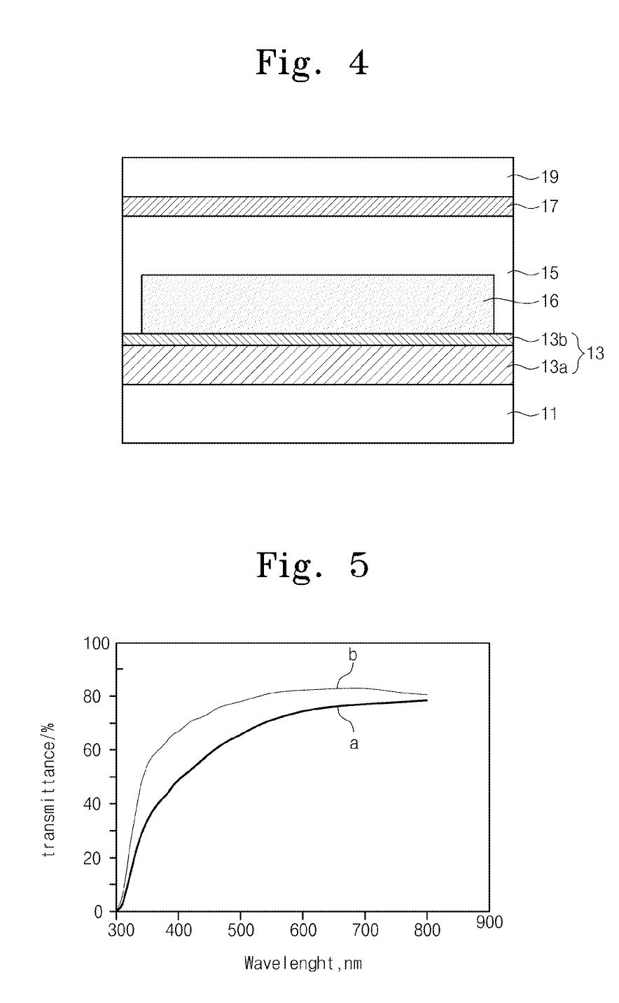

FIG. 4 is a cross-sectional view illustrating a solar cell including a transparent electrode according to exemplary embodiments of the inventive concept.

Referring to FIG. 4, a dye-sensitized solar cell may include a lower substrate 11, a lower transparent electrode 13, a semiconductor electrode layer 16, an upper electrode 17, and an upper substrate 19. The lower transparent electrode 13, the semiconductor electrode layer 16, the upper electrode 17, and the upper substrate 19 may be sequentially stacked on the lower substrate 11. The dye-sensitized solar cell may further include an electrolytic solution layer 15 provided between the semiconductor electrode layer 16 and the upper electrode 17.

The lower substrate 11 may be a glass substrate or a transparent polymer substrate on which a polymer layer is coated.

The lower transparent electrode 13 may include a transparent conductive oxide (TCO) substrate 13a and a metal oxide thin layer 13b. The lower transparent electrode 13 may have a refractive index higher than a refractive index of the lower substrate 11. The transparent conductive oxide substrate 13a may be a glass substrate on which a transparent conductive material is coated. The transparent conductive material may be, for example, indium tin oxide (ITO), F-doped tin oxide (FTO; F-doped SnO₂), zinc oxide (ZnO), or antimony tin oxide (ATO).

The metal oxide thin layer 13b may be formed on the transparent conductive material of the transparent conductive oxide substrate 13a. The metal oxide thin layer 13b may include the conductive particles and the metal oxide combined with the conductive particles. The conductive particle may be the conductive particles functionalized with —NH₂. The conductive particle may be combined with a metal oxide precursor. In more detail, the —NH₂ functional group of the conductive particle may be combined with the —C═O group of a metal oxide precursor ion to form the metal oxide thin layer including the —C═N bond. The conductive particle may be, for example, a silicon particle. The metal oxide may be, for example, zinc oxide (ZnO). The silicon particle may have a size of several nm to several tens nm.

The electrolytic solution layer 15 may include a redox iodide electrolyte. For example, the electrolytic solution layer 15 may be I₃⁻/I⁻ electrolyte solution layer, which may be formed by dissolving 0.7M 1-vinyl-3-methyloctyl-immidazoliuim iodide, 0.1M LiI and 40 mM 12 into 3-methoxypropionitrile. Alternatively, the electrolytic solution layer 15 may be an acetonitrile solution containing 0.6M butylmethylimidazolium, 0.02M I₂, 0.1M Guanidinium thiocyanate, and 0.5M 4-tert-butylpyridine.

The semiconductor electrode layer 16 may include metal oxide particles (not shown) and dye particles (not shown). The dye particles may be adsorbed on surfaces of the metal oxide particles. Each of the metal oxide particles may have one of various shapes of nano sizes. For example, the metal oxide particle may have one of a nanotube-shape, a nano rod-shape, a nanohom-shape, a nanosphere-shape, a nanofiber-shape, a nanoring-shape, and a nanobelt-shape. The metal oxide particles may be formed of titanium dioxide (TiO₂), tin dioxide (SnO₂), zinc oxide (ZnO), tungsten oxide (WO₃), niobium oxide (Nb₂O₅), titanium-strontium oxide (TiSrO₃), or any combination thereof.

The upper electrode 17 may include platinum (Pt), gold (Au), ruthenium (Ru), and/or carbon nanotube. The upper electrode 17 may further include a catalyst layer.

The upper substrate 19 may be a glass substrate or a transparent polymer substrate on which a polymer layer is coated.

The metal oxide thin layer 13b may be coated on the transparent conductive oxide substrate 13a to form the lower transparent electrode 13. The lower transparent electrode 13 has the higher refractive index than the lower substrate 11. Thus, an external light incident on the dye-sensitized solar cell may not be reflected by an interface between the lower substrate 11 and the lower transparent electrode 13. Thus, the light may be inputted into the semiconductor electrode layer 16. As a result, the luminance efficiency of the dye-sensitized solar cell may be improved. In another embodiment, the lower transparent electrode 13 having the high refractive index may be used for other solar cells except the dye-sensitized solar cell.

FIG. 5 is a graph illustrating a transmittance of a transparent electrode according to exemplary embodiments of the inventive concept.

In FIG. 5, a reference designator a shows a transmittance of an F-doped tin oxide (FTO; F-doped SnO₂) substrate, and a reference designator b shows a transmittance of an FTO substrate on which the zinc oxide combined with the silicon particles according to the experiment example is coated.

As illustrated in FIG. 5, the transmittance of the FTO substrate b including the zinc oxide thin layer is greater than the transmittance of the FTO substrate a.

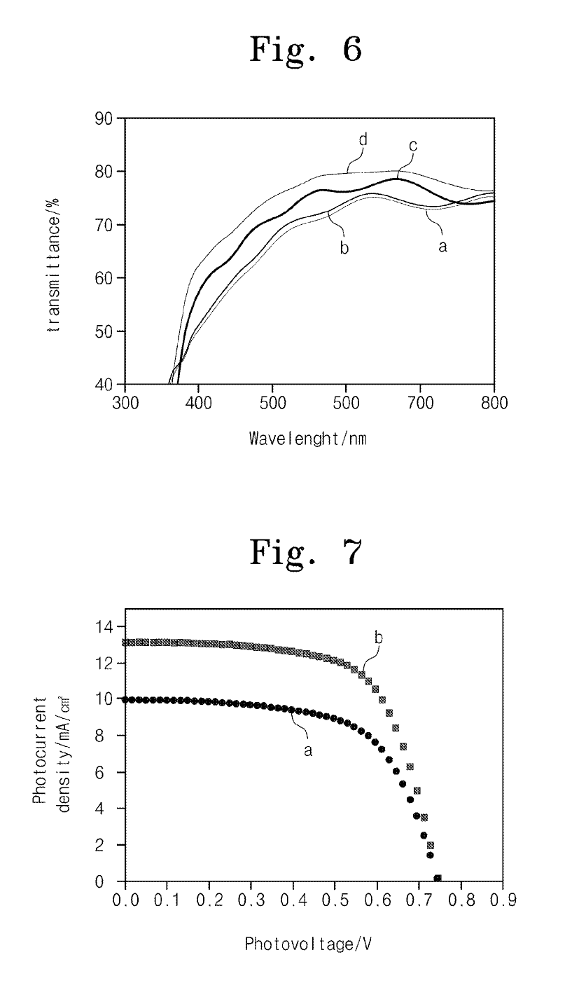

FIG. 6 is a graph illustrating a transmittance of a zinc oxide thin layer including a silicon particle according to exemplary embodiments of the inventive concept.

In FIG. 6, a reference designator a shows a transmittance of an F-FTO substrate, and a reference designator b shows a transmittance of an FTO substrate on which silicon particles are coated. A reference designator c shows a transmittance of an FTO substrate on which zinc oxide particles are coated, and a reference designator d shows a transmittance of an FTO substrate on which the zinc oxide combined with the silicon particles according to the experiment example is coated.

As illustrated in FIG. 6, the transmittance of the FTO substrate including the zinc oxide combined with the silicon particles is greater than those of other substrates.

FIG. 7 is a graph illustrating a voltage-current characteristic of a solar cell including a transparent electrode according to exemplary embodiments of the inventive concept.

In FIG. 7, a reference designator a illustrates a solar cell using a transparent electrode formed of TiO₂, and a reference designator b illustrate a solar cell including a TiO₂ transparent electrode substrate and the zinc oxide combined with the silicon particles according to the experiment example.

As illustrated in FIG. 7, a photocurrent of the solar cell b is greater than a photocurrent of the solar cell a. In other words, the amount of light absorbed into the solar cell b may be greater than the amount of light absorbed into the solar cell a.

According to embodiments of the inventive concept, the transparent electrode has the high refractive index. Thus, the external light incident on the solar cell may not be reflected by the interface between the lower substrate and the transparent electrode. As a result, the external light may be mostly incident on the semiconductor electrode layer, such that the luminance efficiency of the dye-sensitized solar cell may be improved.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A method of fabricating a transparent electrode, the method comprising:
preparing conductive nanoparticles;
preparing a metal oxide sol;
mixing and reacting the conductive nanoparticles with the metal oxide sol to form a metal oxide solution including a metal oxide combined with the conductive nanoparticles;
coating the metal oxide solution on a substrate; and
performing an annealing process on the coated metal oxide solution.

2. The method of claim 1, wherein preparing the conductive nanoparticles comprises:
forming conductive nanoparticles having hydrogen end-groups; and
reacting the conductive nanoparticles having the hydrogen end-groups with an organic compound to form the conductive nanoparticles.

3. The method of claim 2, wherein forming the conductive nanoparticles having the hydrogen end-groups comprises:
preparing a solvent in which a compound including conductive ions dissolves;
preparing an organic compound solvent including a reductant; and
mixing and reacting the solvent including the conductive ions with the organic compound solvent including the reductant to form the conductive nanoparticles having the hydrogen end-groups.

4. The method of claim 3, wherein the organic compound solvent includes allylamine (C₃H₅NH₂).

5. The method of claim 3, wherein the reductant includes a lithium-aluminum hydride (LiAlH₄) solution.

6. The method of claim 1, wherein the conductive nanoparticles are silicon particles functionalized with —NH₂.

7. The method of claim 1, wherein preparing the metal oxide sol comprises:
preparing a metal oxide precursor solution;
dissolving the metal oxide precursor solution in an organic solvent mixed with an alcohol-based solution; and
reflexing the organic solvent including the metal oxide precursor solution.

8. The method of claim 7, wherein the metal oxide precursor solution includes zinc acetate dehydrate [Zn(CH₃COO)₂.(2H)₂O].

9. The method of claim 7, wherein the organic solvent includes ethanolamine (CHOC₂CH₂NH₂).

10. The method of claim 7, wherein the alcohol-based solution is a mixed solution of methanol and 2-methoxy ethanol in a ratio of 1:1.

11. The method of claim 1, wherein the conductive nanoparticle is combined with the metal oxide by —C═N bond

12. A dye-sensitized solar cell comprising:
a lower substrate;
a lower transparent electrode disposed on the lower substrate;
a semiconductor electrode layer disposed on the lower transparent electrode; and
an upper electrode disposed on the semiconductor electrode layer,
wherein the lower transparent electrode includes a transparent conductive oxide substrate and a metal oxide thin layer coated on the transparent conductive oxide substrate; and
wherein the metal oxide thin layer includes a metal oxide combined with conductive particles. 15

13. The dye-sensitized solar cell of claim 12, wherein the lower transparent electrode has a refractive index higher than a refractive index of the lower substrate.

14. The dye-sensitized solar cell of claim 12, wherein the conductive particles are silicon particles.

15. The dye-sensitized solar cell of claim 12, wherein the metal oxide is zinc oxide (ZnO).

16. The dye-sensitized solar cell of claim 12, wherein the conductive particle has a nanometer size.
